(19) United States
(12) Patent Application Publication
(10) Pub. No.: US 2026/0156973 A1
(43) Pub. Date: Jun. 4, 2026

(54) METHOD FOR MANUFACTURING AN OPTOELECTRONIC DEVICE

(71) Applicant: ALEDIA, Echirolles (FR)

(72) Inventor: Emmanuel PETITPREZ, Grenoble (FR)

(21) Appl. No.: 18/714,898

(22) PCT Filed: Nov. 30, 2022
(86) PCT No.: PCT/EP2022/083944

§ 371 Date: May 30, 2024

(30) Foreign Application Priority Data
Dec. 7, 2021 (FR) FR2113065

(51) Int. Cl. H10H 20/813; H10H 20/01

(52) U.S. Cl. CPC H10H 20/8132; H10H 20/017

(57) ABSTRACT

A method for manufacturing an optoelectronic device including a first area including a plurality of three-dimensional structures, and a second area free of said 3D structures, the method including at least a provision of a substrate including a surface layer enabling the nucleation and the growth of the 3D structures, a formation of a buffer layer covering the substrate at the second layer, without covering the first area, a growth of the 3D structures in the first area starting from the surface layer, the growth forming residues above the buffer layer, in the second area, and a first etching configured to eliminate the residues and to stop in the buffer layer.

### TECHNICAL FIELD OF THE INVENTION

The invention relates to the field of semiconductor technologies. It finds a particularly advantageous application in the manufacture of optoelectronic devices comprising three-dimensional structures, for example light-emitting diodes based on semiconductor wires or nanowires, laser, photodetectors or solar cells.

### PRIOR ART

The so-called 3D architectures of microelectronic and optoelectronic devices based on arrays of three-dimensional semiconductor structures, such as nanowires or microwires, are considered promising alternatives to conventional architectures based on two-dimensional semiconductor structures, such as planar layers.

Such 3D architecture devices may have an improved overall efficiency. Ordered arrays of nanowires based on a semiconductor material such as GaN, or more generally based on a direct gap material for optoelectronics, often have a crystalline quality higher than that of a planar layer based on the same material. For example, this allows improving the light emission of an optoelectronic device such as a light-emitting diode with a 3D architecture (3D LED). The optical properties of such arrays also improve light extraction.

The manufacture of functional optoelectronic devices with a 3D architecture requires structuring the ordered arrays of 3D structures, for example to define contact areas of the device. Other areas of the plate (or wafer) over which the nanowires are formed also need to be free of said nanowires. This is the case for example of the areas dedicated to ellipsometric measurements, which should be planar. This is also the case of the areas comprising alignment marks for lithography, which should remain visible.

Several known solutions allow forming an area free of 3D structures.

A solution disclosed in the document US 2010/116780 A1 consists, prior to the growth of the nanowires, in providing for sacrificial layers located at the areas that should be devoid of nanowires. Afterwards, the growth is performed in a “full-wafer” fashion, and the nanowires that have grown over the sacrificial layers are removed by lift off, by dissolving the sacrificial layers. Yet, in practice, the nanowires do not grow in an ideal manner over the masked areas such as the sacrificial layers. More compact growth residues may form with or instead of the nanowires. These parasitic residues and/or growths generate a surface roughness having remarkable drawbacks. For example, this surface roughness diffracts the light and makes the visualisation of underlying structures difficult and even impossible. In addition, the presence of this surface roughness makes the metrology of thin layers by optical techniques such as ellipsometry, interferometry or scatterometry impossible. These residues are more difficult to eliminate by lift off than the sacrificial layers.

The document US 2016/0276433 A1 discloses steps of a method allowing making nanowires grow starting from an area of a substrate while protecting, by a masking layer, a neighbouring area over which nanowires having other characteristics will subsequently grow. Afterwards, the masking layer covering the neighbouring area is removed by etching. However, this solution does not enable an adequate removal of the growth residues that would have been deposited over the masking layer, in particular when these residues extend over a considerable proportion of the surface larger than the masking layer. Indeed, in this case, the masking layer is barely accessible and a considerable proportion of the masking layer is not properly etched. The obtained result following the etching is then unsatisfactory, since both portions of the masking layer and growth residues persist.

The present invention aims to at least partially overcome the above-mentioned drawbacks.

In particular, an object of the present invention is to provide a method for manufacturing a 3D optoelectronic device allowing eliminating parasitic growths at some determined areas.

Other purposes, characteristics and advantages of this invention will appear upon reading the following description and its accompanying drawings. It is understood that other advantages can be incorporated thereto.

### SUMMARY OF THE INVENTION

To achieve the above-mentioned objectives, a first aspect relates to a method for manufacturing an optoelectronic device comprising a first area comprising a plurality of three-dimensional (3D) structures, and a second area free of said 3D structures.

The method comprises at least a provision of a substrate comprising a surface layer enabling the nucleation and the growth of the 3D structures, a formation of a buffer layer covering the substrate at the second layer, without covering the first area, a growth of the 3D structures in the first area starting from the surface layer, said growth forming residues above the buffer layer, in the second area, and a first etching configured to eliminate the residues and to stop in the buffer layer.

Thus, during the growth of the 3D structures, the parasitic growths occur on the buffer layer. Thus, the topography transfer that accompanies the first etching, typically anisotropic, takes place over or in the buffer layer, which, in turn, may then be selectively removed off the underlayer, for example during a second isotropic etching.

Hence, the buffer layer allows avoiding the topography of the residues being transferred into the underlayer during the first etching of the residues. Thus, the method allows advantageously obtaining, after removal of the buffer layer, a planar surface, with no growth and with roughness. In particular, such a planar surface is necessary during some manufacturing and metrology steps, for example during ellipsometric measurements. This also allows making the patterns present over the substrate (for example alignment marks) visible, these patterns may be necessary following the manufacturing method.

Another aspect of the invention relates to a device comprising a substrate, a first area comprising a plurality of 3D structures and a second area comprising a buffer layer topped by residues.

Advantageously, the second area comprises no 3D structures and the buffer layer has a thickness strictly larger than a maximum thickness of the residues, so that said buffer layer can absorb a transfer of topography of the residues during an etching of the residues.

### BRIEF DESCRIPTION OF THE FIGURES

The aims, objects, as well as the features and advantages of the invention will appear better from the detailed description of embodiments of the latter which are illustrated by the following appended drawings wherein:

FIG. 1 illustrates the substrate.

FIG. 2 illustrates the deposition of a nucleation layer over the substrate.

FIG. 3 illustrates the deposition of a masking layer over the nucleation layer.

FIG. 4 illustrates the full-wafer deposition of a buffer layer over the masking layer.

FIG. 5 illustrates the reduction of the buffer layer to the dimensions of an area of interest.

FIG. 6 illustrates the formation of openings in the masking layer.

FIG. 7 illustrates the growth by epitaxy of 3D structures throughout the masking layer as well as parasitic growths taking place over the buffer layer.

FIG. 8 illustrates the formation of an encapsulation around the 3D structures.

FIG. 9 illustrates etching of the parasitic growths present over the buffer layer.

FIG. 10 illustrates etching of the buffer layer and of the encapsulation.

FIG. 11 illustrates the full-wafer deposition of an additional masking layer, an optional step may take place after the step illustrated in FIG. 5.

FIG. 12 illustrates, in the case where the step described in FIG. 11 has been implemented, the formation of openings in the masking layer and the additional masking layer, which step therefore forms a variant to the step illustrated in FIG. 6.

FIG. 13 illustrates an embodiment wherein a space is left between the sidewall of the encapsulation and the sidewall of the additional masking later surrounding the buffer layer.

FIG. 14 illustrates etching of the parasitic growths present over the buffer layer.

FIG. 15 illustrates etching of the buffer layer.

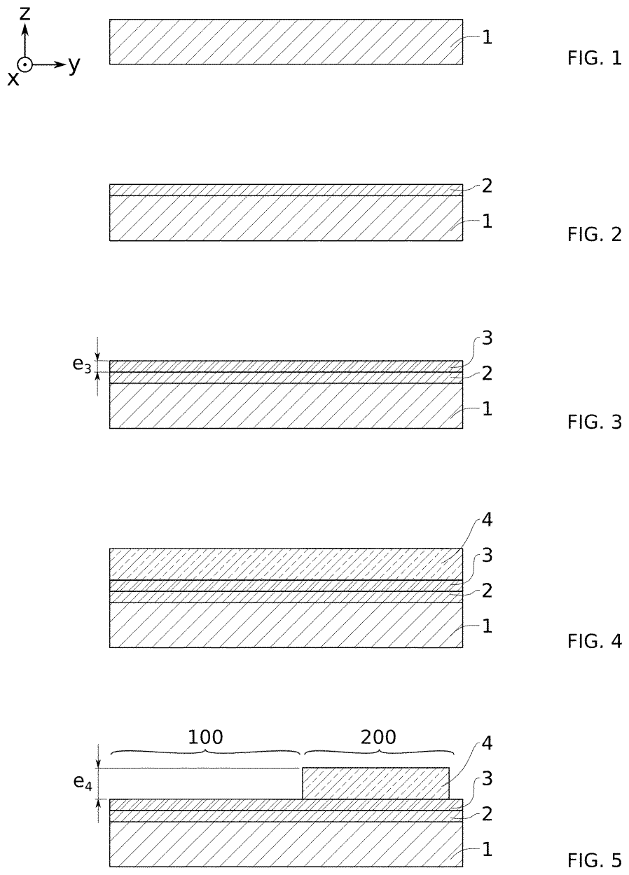

The drawings are provided by way of example and are not intended to limit the scope of the invention. They constitute diagrammatic views intended to ease the understanding of the invention and are not necessarily to the scale of practical applications. In particular, the dimensions of the different elements of the optoelectronic device are not necessarily representative of reality.

### BRIEF DESCRIPTION OF THE FIGURES

Before starting a detailed review of embodiments of the invention, it should be recalled that the invention comprises in particular the optional features hereinafter which may be used in combination or alternatively.

According to one embodiment, the method further comprises a second etching, configured to eliminate the buffer layer. Preferably, the second etching has a selectivity higher than or equal to 1:1, and preferably higher than or equal to 5:1, between the material of the buffer layer and the material of the layer beneath the buffer layer, typically a masking layer.

According to one embodiment, the method further comprises a deposition of a masking layer over the surface layer and a formation of openings in said masking layer at the first area, so as to expose the surface layer throughout said openings. In this example, the buffer layer is formed over the masking layer and the growth of the 3D structures is done throughout the openings of the masking layer.

According to one example, the second etching is configured to eliminate the buffer layer selectively with the masking layer.

According to one example, the method comprises a formation of an encapsulation of the 3D structures, before the first etching.

According to one example, the encapsulation is formed so as to leave a space between said encapsulation and the buffer layer. Typically, this space defines a third area between the first and second areas.

According to one example, the method comprises a full-wafer deposition of an additional masking layer after the formation of the buffer layer, and a formation of openings throughout said additional masking layer and the masking layer.

According to one example, the additional masking layer is based on the same material as that of the masking layer.

According to one embodiment, the first etching is configured to remove a portion of the additional masking layer covering the buffer layer.

According to one example, the masking layer and the additional masking layer respectively have thicknesses e₃ and e₉ such that e₃+e₉≤500 nm.

According to one example, the additional masking layer is deposited such that a space is preserved between the sidewall of the encapsulation and a portion of the additional masking layer disposed against a sidewall of the buffer layer.

According to one example, the encapsulation is disposed so as to leave a space between said encapsulation and the additional masking layer surrounding the buffer layer.

According to one example, the first etching is anisotropic.

According to one example, the second etching is anisotropic.

According to one example, the formation of the buffer layer is configured so that the buffer layer completely covers, projected in a base plane (xy), an underlying area of interest selected from among an alignment mark areas, an optical measurement area (for example: ellipsometry measurement, reflectivity measurement), an electrical measurement area (for example: current, voltage, capacitance measurement . . . ), topographic or morphologic measurements (for example: roughness) or any other area or pattern of interest.

According to one example, the definition of the buffer layer is done by photolithography.

According to one example, the 3D structures are based on a III-V material such as GaN, GaAs, InP.

According to one example, the first etching has a selectivity higher than or equal to 5:1, and preferably higher than or equal to 10:1, between the material of the buffer layer and the material of the masking layer.

According to one example, the formation of the openings of the masking layer is done after deposition of the buffer layer.

According to an embodiment of the second aspect of the invention, relating to a device, the thickness of the buffer layer is at least twice as large as the thickness of the residues.

According to one example, the residues cover more than 50%, preferably from 85 to 100% of the upper face of the buffer layer.

According to one example, the device comprises an encapsulation covering the 3D structures.

According to one example, the device comprises a masking layer over the substrate and openings in the masking layer at the first area, the 3D structures extending throughout said openings.

According to one embodiment, the device comprises an additional masking layer in contact with the buffer layer and beneath the residues, wherein the buffer layer has a thickness strictly larger than the sum of the maximum thickness of the residues and of a thickness of said additional masking layer.

In the present invention, the method is dedicated in particular to the manufacture of light-emitting diodes based on semiconductor structures or microstructures such as semiconductor wires or nanowires, semiconductor pyramidal structures or else semiconductor nanometric walls (nano-walls).

More generally, the invention may be implemented for different optoelectronic devices, and possibly for MEMS electromechanical devices or microsystems. For example, the invention may be implemented in the context of laser or photovoltaic devices.

Unless stated otherwise, it is specified that, in the context of the present invention, the relative arrangement of a third layer interposed between a first layer and a second layer, does not necessarily mean that the layers are directly in contact with each other, but means that the third layer is either directly in contact with the first and second layers, or separated from these by at least one other layer or at least one other element.

Thus, the terms and locutions “bear” and “cover” or “overlay” do not necessarily mean “in contact with”.

The steps of the method as claimed should be understood in a broad sense and may possibly by carried out into several sub-steps.

In the present patent application, the terms “light-emitting diode”, “LED” or simply “diode” are used as synonyms. A “LED” may also be understood as a “nano-LED”, a “micro-LED”.

A portion or an element described as “sacrificial”, means that this element is intended to be “sacrificed”, i.e. removed during a subsequent step of the method.

By a substrate, a layer, a device, “based” on a material M, it should be understood a substrate, a layer, a device comprising this material M alone or this material M and possibly other materials, for example, alloy elements, impurities or doping elements. Thus, a GaN-based diode typically comprises GaN and AIGaN or InGaN alloys.

Moreover, a layer may be composed of several sub-layers of the same material or of different materials.

By “selective etching with respect to” or “etching having a selectivity with respect to”, it should be understood an etching configured to remove a material A or a layer A off a material B or a layer B, and having an etching rate of the material A higher than the etching rate of the material B. The selectivity is the ratio between the etching rate of the material A to the etching rate of the material B. The selectivity between A and B is denoted S_{A:B}.

A reference frame, preferably orthonormal, comprising the axes x, y, z is represented in some appended figures. This reference frame is applicable by extension to the other figures of the same figure sheet.

In the present patent application, we will preferably talk about thickness for a layer and height for a structure or a device. The thickness is considered according to a direction normal to the main plane of extension of the layer, and the height is considered perpendicularly to the base plane xy. Thus, a layer typically has a thickness according to z, when it primarily extends along a plane xy, and a projecting element, for example an insulation wafer, has a height according to z. The relative terms “over”, “under”, “underlying” preferably refer to positions taken according to the direction z.

The dimensional values should be understood within manufacturing and measurement tolerances.

The terms “substantially”, “about”, “in the range of” mean, when they relate to a value, “within 10%” of this value or, when they relate to an angular orientation, “within 10°” of this orientation. Thus, a direction substantially normal to a plane means a direction having an angle of 90±10° with respect to the plane.

In the present patent application, by “a first area” or “a second area”, it should be understood an area which is not necessarily continuous and which can thus be defined by a plurality of sub-areas.

The term “3D structure” should be understood in contrast with so-called planar or 2D structures, which have two dimensions in a plane larger than the third dimension normal to the plane. Thus, the usual 3D structures targeted in the 3D LED field may be in the form of wires, nanowires or microwires, pyramids or nanopyramids or else nano-walls. A 3D structure in the form of a wire, a microwire or nanowire, for example, has an elongate shape according to the longitudinal direction. The longitudinal dimension of the wire, according to z in the figures, is larger, and preferably quite larger, than the transverse dimensions of the wire, in the plane xy in the figures. For example, the longitudinal dimension is at least five times, and preferably at least ten times, as large as the transverse dimensions. The 3D structures may also be in the form of walls. In this case, only one transverse dimension of the wall is quite smaller than the other dimensions, for example at least five times, and preferably at least ten times, as small as the other dimensions. The 3D structures may also be in the form of pyramids.

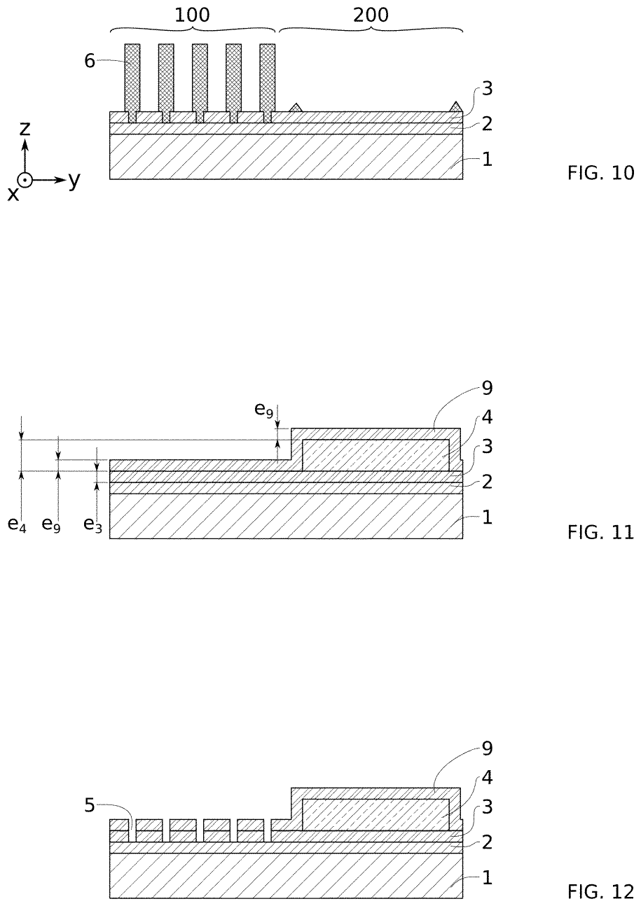

FIG. 10 illustrates the result that the method according to the invention allows obtaining: a plate where some areas have at their surface 3D structures 6 evenly distributed and homogeneous, and where other areas are free of these same 3D structures.

In the following examples, the 3D structures 6 are semiconductor nanowires. It should be understood that the method is perfectly suitable to other types of 3D structures, for example and without limitation: pyramids, fins.

Preferably, the nanowires extend longitudinally according to z. They may have a height comprised between a few tens of nanometres and several micrometres, for example larger than or equal to 100 nm and smaller than or equal to 20 μm. They may have different shapes, in section in the plane xy. Typically, the GaN-based nanowires have a substantially hexagonal section. The maximum dimension of the nanowires in the plane xy, for example the diameter, may be comprised between a few tens of nanometres and several micrometres, for example between 50 nm and 5 μm. They have an apex and a base. Their base bears on the substrate 1. Preferably, they are substantially parallel to each other and evenly distributed over the substrate 1.

In this example, the nanowires 6 are typically obtained by growth starting from a surface layer, or nucleation layer 2 deposited over a substrate 1, throughout openings 5 in a masking layer 3.

In particular, the substrate 1 may be made of sapphire to limit the mesh parameter discrepancy with GaN, or of silicon to reduce costs and for technological compatibility problems. In the latter case, it might be in the form of a wafer with a diameter of 200 mm or 300 mm. In particular, it serves as a support to the 3D structures.

According to one example, the substrate 1 comprises a nucleation layer 2, typically comprising one or more sublayers of the same material or of different materials. Preferably, the nucleation layer 2 is based on AlN. Alternatively, it may be based on metal nitrides, for example GaN or AlGaN. This nucleation layer 2 may comprise any layer known to a person skilled in the art enabling the nucleation and the growth of the material forming the 3D structures 6, for example GaN. It may be formed over the substrate 1 by epitaxy, preferably by MetalOrganic Vapour Phase Epitaxy MOVPE, by Molecular Beam Epitaxy MBE or by Chemical-Vapour Deposition CVD, typically by halogenated CVD. Advantageously, it has a thickness smaller than or equal to 200 nm, preferably smaller than or equal to 100 nm, for example in the range of 50 nm. This allows limiting the mechanical stresses induced by this layer 2 on the substrate 1. This allows avoiding a detrimental curvature of the substrate 1. Such a thickness further allows limiting the apparition of structural defects in the nucleation layer 2. In particular, the growth of this nucleation layer 2 may be pseudomorphic, i.e. the epitaxy stresses (related in particular to the difference in mesh parameters between Si and AlN, GaN or AlGaN) may be elastically relieved during the growth. Thus, the crystalline quality of this nucleation layer 2 may be optimised.

Preferably, the masking layer 3 is made of a dielectric material, for example of silicon nitride Si3N4, or of SiO2. It can be deposited by Chemical-Vapour Deposition CVD over the nucleation layer 2. It partially masks the nucleation layer 2 and comprises openings 5, preferably circular, exposing portions of the nucleation layer 2. Typically, these openings 5 have a dimension, for example a diameter Φ₀ or an average diameter, comprised between 30 nm and 2 μm. The openings 5 may be evenly distributed within the masking layer 3, for example in the form of an ordered array. The step, i.e. the distance separating the centres of two adjacent openings 5, is smaller than or equal to 10 μm, and preferably smaller than or equal to 5 μm. Advantageously, it is comprised between 100 nm and 5 μm, and even more advantageously between 100 nm and 2 μm. Advantageously, the openings 5 have a surface density higher than 0.01 μm⁻², and more advantageously, higher than 0.04 μm⁻² . In fine, this allows obtaining densely distributed 3D structures over the substrate 1. If an additional masking layer 9 has been full-wafer deposited as illustrated in FIG. 11, the openings 5 are made simultaneously throughout the masking layer 3 and the additional masking layer 9, and their height is preferably equal to the sum of the thicknesses of the masking layer 3 and of the additional masking layer 9. For example, these openings 5 may be made by chlorinated or fluorocarbonated chemistry dry anisotropic etching, by UV or DUV (acronym of Deep UV) lithography, by electron beam lithography, or by NIL (acronym of NanoInprint Lithography). Such a masking layer 3 allows for a localised growth of a 3D structure at each opening 5. In particular, during a preliminary growth step called germination, a GaN-based seed is formed at the opening 5 and then fills said opening 5. The subsequent growth of the 3D structure 6 is then done starting from this seed, in a localised manner.

The buffer layer 4 may be made of SiO2, SIN or SiON, of refractory metal nitrides such as TIN, WN or TaN, of a refractory metal such as W, Ti or Ta, of a metal oxide such as Al2O3 or TiO2, or else be made based on at least one of these materials. This material should be selected such that it has a good etching selectivity with respect to the material of the masking layer 3 during etching of the buffer layer 4. If the masking layer 3 is made, as given as example, of Si3N4, it is therefore excluded to make the buffer layer 4 of silicon nitride too.

The formation of the GaN-based nanowires 6 may be done by epitaxy, preferably by MetalOrganic Vapour Phase Epitaxy MOVPE. Typically, the source of gallium in the form of an organometallic precursor may be trimethyl-gallium (TMGa) or triethyl-gallium (TEGa). Typically, the source of nitrogen may be ammonium hydroxide (NH3). The flows of the different gases may be adapted in a manner known to a person skilled in the art, in particular according to the volume of the reactor.

Alternatively, the formation of the nanowires 6 may be done by Molecular Beam Epitaxy MBE, by Hydride Vapour Phase Epitaxy HVPE, by Chemical-Vapour Deposition CVD and MetalOrganic Chemical-Vapour Deposition MOCVD.

Optionally, conventional steps of preparing the surface of the seed (chemical cleaning, heat treatment) may be performed prior to the epitaxial growth of the nanowires 6.

The nanowires may comprise a N-doped GaN based region. In a known manner, this N-doped region may result from a growth, an implantation and/or an activation annealing. In particular, the N doping may be obtained directly during the growth, starting from a silicon or germanium source, for example by addition of silane or disilane or germane vapour. The growth conditions required for the formation of such nanowires are widely known.

The encapsulation 8 may be made of resin, whether photosensitive or not, or be based on inorganic materials such as SiO2.

The removal of the GaN-based residues or parasitic growths 7 deposited over the buffer layer 4 during the formation of the nanowires 6 is preferably done by means of a chlorinated plasma dry etching. It may consist of a Reactive-lon Etching RIE or Inductively coupled Plasma Reactive-lon Etching ICP-RIE. For example, the chlorinated precursor may be based on Cl2, BCl3 or a mixture of these two compounds. The removal of the parasitic growths 7 may also be done by lon Beam Etching IBE.

In the advantageous embodiment wherein an encapsulation 8 of the 3D structures is formed before the step of removing the residues, this encapsulation 8 allows limiting and possibly preventing the degradation of the 3D structures during the first etching. Thus, preferably, the material of the buffer layer 4 and the material of the encapsulation 8 are distinct. Advantageously, the first etching has a selectivity higher than or equal to 1:1, preferably higher than or equal to 5:1, between the material of the buffer layer 4 and the material of the encapsulation 8. This allows limiting the degradation of the encapsulation and therefore limiting the degradation of the 3D structures during the first etching.

Similarly, the encapsulation 8 allows protecting the 3D structures during a second etching aiming to eliminate the buffer layer 4. Hence, resorting to distinct materials for the buffer layer 4 and the encapsulation layer is also advantageous in the context of this second etching. Advantageously, the second etching has a selectivity higher than or equal to 1:1, preferably higher than or equal to 5:1, between the material of the buffer layer 4 and the material of the encapsulation 8. This allows limiting the degradation of the encapsulation and therefore limiting the degradation of the 3D structures during the second etching.

A high selectivity—typically higher than 5:1—during the first and/or second etching between the material of the buffer layer and the material of the encapsulation layer may in particular by obtained by implementing a wet etching. This is in particular the case when the encapsulation 8 is made of resin.

If an additional masking layer 9 has been full-wafer deposited as illustrated in FIG. 11, it is possible to configure the etching of the parasitic growths 7 to simultaneously etch the underlying additional masking layer 9, as illustrated in FIG. 14. For this purpose, it is preferable that the thickness e₉ of the additional masking layer 9 is smaller than 50 nm. This allows facilitating the simultaneous etching of the two layers.

The growth of the parasitic growths 7 has the drawback of transferring the topography of these same parasitic growths 7 to the underlayer. According to the invention, this underlayer is formed by the additional masking layer 9, if such a layer has been deposited, and by the buffer layer 4. In the case where an additional masking layer 9 protects the buffer layer 4 of this first etching, this same additional masking layer 9 should be entirely etched above the area of interest and the buffer layer 4 should be etched too. Thus, it is necessary to guarantee that the thickness e₄ of the buffer layer 4 is enough to absorb the first etching and avoid damaging of the masking layer 3. Thus, preferably, the buffer layer 4 has a minimum thickness of 100 nm. Advantageously, the thickness e₄ of the buffer layer 4 is larger than the maximum thickness eₘₐₓ of the parasitic growths 7 so that said buffer layer 4 could absorb a transfer of the topography of the parasitic growths 7 during etching of these same parasitic growths 7. Preferably, the ratio between the thickness e₄ of the buffer layer 4 and the maximum thickness e₇ₘₐₓ of the parasitic growths 7 is higher than 2, preferably higher than 5. Sizing of the thickness of the buffer layer 4 and/or of the additional masking layer 9 is performed so as to absorb the topography transfer related to etching of the parasitic growths 7.

The selective removal of the buffer layer 4 may be done by wet isotropic etching. It is possible to use a HF solution for a buffer layer 4 made of SiO2, a H3PO4 solution for a buffer layer 4 made of SIN, a solution having volume ratios varying between 5:1:1 and 7:2:1 of H2O, H2O2, and NH4OH respectively (for example the Standard Clean 1® solution) for a buffer layer 4 made of metal nitride, and a HCl solution for a buffer layer 4 made of metal. The wet etchings allow for very high etching selectivities, for example between SiO2 and Si3N4 and between TiN and SiO2. A dry etching is also possible, provided that it is selective enough with respect to the underlayer.

The removal of the encapsulation 8 is done by processes well known in the microelectronics industry, such as a dry or wet etching. This removal should be done selectively with respect to the nanowires.

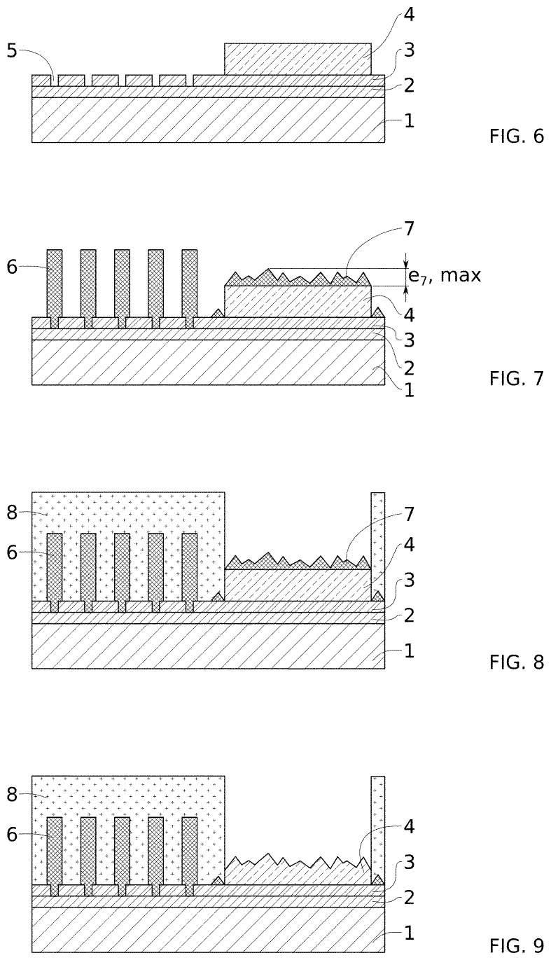

Moreover, if an additional masking layer 9 is not deposited later on, it is possible to consider carrying out the step illustrated in FIG. 6 before that one illustrated in FIG. 5. However, it is preferable to make openings 5 in the masking layer 3 after the formation of the buffer layer 4. This allows avoiding the deterioration of said openings 5 during the deposition and/or structuring of said buffer layer 4, thereby ensuring conferring the shape of the openings 5 as made on the nanowires 6 and guaranteeing a homogeneous growth.

Advantageously, the additional masking layer 9 is full-wafer deposited after deposition of the buffer layer 4 and before the creation of the openings 5 in the masking layer 3 and in the additional masking layer 9.

Indeed, the presence of the buffer layer 4, and therefore of metal oxide, nitride or else of a refractory metal, might disturb the growth of the 3D structures. Thus, the additional masking layer 9, deposited after the buffer layer 4, allows isolating the step of epitaxy of the buffer layer 4 and therefore improving the growth of the nanowires 6 close to the buffer layer 4.

Preferably, the additional masking layer 9 is made of the same material as the masking layer 3. This allows obtaining a homogeneous environment for the growth of the GaN nanowires 6 and therefore obtaining a homogeneous growth.

Advantageously, the sum of the thicknesses of the masking layer 3 and of the additional masking layer 9 is smaller than 500 nm, preferably in the range of 80 nm. This results in facilitating the growth of the nanowires 6 throughout the openings 5.

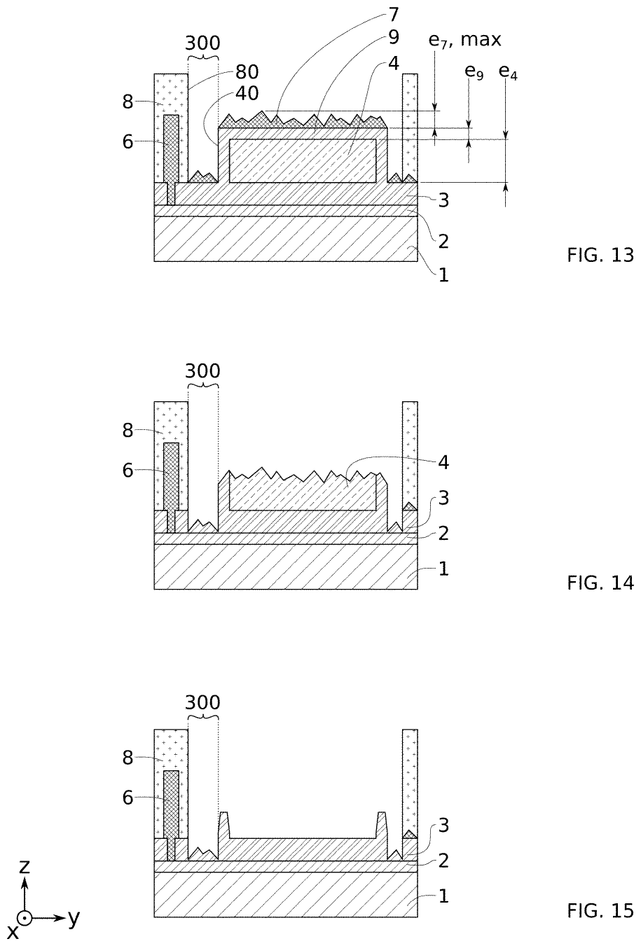

Preferably, as illustrated in FIG. 13, the encapsulation 8 is disposed so as to leave a space between said encapsulation 8 and the buffer layer 4. Typically, this space defines a third area 300 between the first area 100 and the second area 200. Leaving such a space between the encapsulation 8 and the buffer layer 4 allows tolerating a possible misalignment between the location of the buffer layer 4 and the formation of the encapsulation 8, typically defined by a mask aligner. This also allows improving access to isotropic etching solutions. Thus, etching of the additional masking layer 9 and/or of the buffer layer 4 is improved.

In an example where the method does not comprise the deposition of an additional masking layer 9, it is also possible and advantageous to leave a space between the sidewall 80 of the encapsulation 8 and the sidewall 40 of the buffer layer 4.

Advantageously, the first etching, or the second etching, or the first and second etchings are anisotropic. Indeed, a normal attack in the plane of the substrate 1 and non in all directions of the space has the advantage of limiting the deterioration of the sidewall 80 of the encapsulation 8 protecting the 3D structures 6, and therefore anticipating any alteration of the 3D structures 6.

Preferably, the surface of the buffer layer 4 projected in the plane of the substrate 1 is configured to completely cover an underlying area of interest selected from among an alignment mark area or an ellipsometric measurement area or any other area or patter of interest whose planarity and/or visibility should be preserved. This allows having a visual access to this underlying area of interest once the buffer layer 4 is removed by etching.

The parameters of the second etching are selected so as to preserve a masking layer thickness 3 after the total etching of the buffer layer 4. More particularly, the rate of etching of the material of the buffer layer 4 is significantly higher than that of the material of the masking layer 3. Preferably, it is five times larger, and even more advantageously, it is ten times larger. A good etching selectivity between these two materials allows, during the second etching, effectively removing the buffer layer 4 without removing or damaging the masking layer 3.

Advantageously, the 3D structures are preferably made of GaN. Alternatively, they may be made of GaInN, GaAs, GaInAs, InP, InAsP, GaSb or a combination of these materials.

The method may also comprise the deposition of other layers, such as an anti-reflective layer deposited over the nucleation layer. In this example, openings are made in the anti-reflective layer, preferably simultaneously with the formation of the openings 5 in the additional masking layer 9 and in the masking layer 3, so as to expose the nucleation layer 2.

In order to address a possible misalignment between the buffer layer 4, whose dimensions are determined for example by placing a photorepeater over alignment marks, and the etching of this same buffer layer 4, whose location rather depends on a mask aligner, the dimensions of the etching area are preferably larger than those of the buffer layer 4.

Therefore, the masking layer 3 close to the buffer layer 4 also undergoes the step of etching the buffer layer 4.

In the case where the additional masking layer 9 has been deposited, the areas of this additional layer 9 deposited against the sidewalls of the buffer layer 4 subsist at least partially after etching of the buffer layer 4, thereby forming excrescences in the direction Z, as represented in FIG. 15.

Both the over-etching and the excrescences of the masking layer 3 are detectable in a cross-section, which forms an indication of the implementation of the present method.

This detection may be performed based on electronic microscopy analysis, in particular by Scanning Electron Microscopy (SEM) or by Transmission Electron microscopy (TEM).

However, the invention is not limited to the previously-described embodiments.

In particular, the number, the shape and the material of the 3D structures may be adapted according to the optoelectronic devices. Materials other than those mentioned may also be used to make the masking layer 3, the buffer layer 4, the additional masking layer 9 and the encapsulation 8.

1. A method for manufacturing an optoelectronic device comprising a first area comprising a plurality of three-dimensional (3D) structures, and a second area free of said 3D structures, said method comprising at least:
a provision of a substrate comprising a surface layer enabling the nucleation and the growth of the 3D structures,
a formation of a buffer layer covering the substrate at the second layer, without covering the first area,
a growth of the 3D structures in the first area starting from the surface layer, said growth forming residues above the buffer layer, in the second area, and
a first etching configured to eliminate the residues and to stop in the buffer layer.

2. The method according to claim 1, comprising a second etching, configured to eliminate the buffer layer.

3. The method according to claim 1, comprising a deposition of a masking layer over the surface layer, and a formation of openings in said masking layer, at the first area, so as to expose the surface layer throughout said openings, wherein the buffer layer is formed over the masking layer and wherein the growth of the 3D structures is done throughout the openings of the masking layer.

4. The method according to claim 3, comprising a second etching, configured to eliminate the buffer layer, and wherein the second etching is configured to eliminate the buffer layer selectively with the masking layer.

5. The method according to claim 1, further comprising a formation of an encapsulation of the 3D structures, before the first etching.

6. The method according to claim 5, wherein the first etching has a selectivity higher than or equal to 1:1, between the material of the buffer layer and the material of the encapsulation.

7. The method according to claim 5, wherein the encapsulation is formed so as to leave a space between said encapsulation and the buffer layer.

8. The method according to claim 3, comprising a full-wafer deposition of an additional masking layer after the formation of the buffer layer, and a formation of openings throughout said additional masking layer and the masking layer.

9. The method according to claim 8, wherein the additional masking layer is based on the same material as that of the masking layer.

10. The method according to claim 8, wherein the first etching is configured to remove a portion of the additional masking layer covering the buffer layer.

11. The method according to claim 8, wherein the masking layer and the additional masking layer respectively have thicknesses e₃ and e₉ such that e₃+e₉≤500 nm.

12. The method according to claim 5, further comprising a full-wafer deposition of an additional masking layer after the formation of the buffer layer, and a formation of openings throughout said additional masking layer and the masking layer, and wherein the additional masking layer is deposited such that a space is preserved between a sidewall of the encapsulation and a portion of the additional masking layer disposed against a sidewall of the buffer layer.

13. The method according to claim 1, wherein the first etching is anisotropic.

14. The method according to claim 2, wherein the second etching is isotropic.

15. The method according to claim 1, wherein the formation of the buffer layer is configured so that the buffer layer completely covers, projected in a base plane, an underlying area of interest selected from among an alignment mark area, an optical measurement area, an electrical measurement area, and a topographic or morphologic measurement area.

16. The method according to claim 15, wherein the underlying area of interest is selected from among an alignment mark area and an ellipsometric measurement area.

17. The method according to claim 1, wherein the definition of the buffer layer is done by photolithography.

18. The method according to claim 1 wherein the 3D structures are based on a III-V material such as GaN, GaAs, InP.

19. The method according to claim 3, wherein the first etching has a selectivity higher than or equal to 5:1, between the material of the buffer layer and the material of the masking layer.

20. The method according to claim 3, wherein the formation of the openings of the masking layer is done after deposition of the buffer layer.

21. The method according to claim 1, wherein the buffer layer has a thickness strictly larger than a maximum thickness of the residues, so that said buffer layer could absorb a transfer of the topography of the residues during an etching of the residues.

22. The method according to claim 21, wherein the thickness of the buffer layer is at least twice as large as the maximum thickness of the residues.
